(19) United States
(12) Patent Application Publication
(10) Pub. No.: US 2008/0277684 A1
(43) Pub. Date: Nov. 13, 2008

(54) SURFACE LIGHT EMITTING DIODE MODULE WITH A SURFACE LIGHT EMITTING DIODE CONNECTED TO A CONDUCTIVE SUBSTRATE TIGHTLY

(76) Inventors: Chen-Hsiu Lin, Taipei Hsien (TW); Ming-Yen Chen, Taipei County (TW)

Correspondence Address: NORTH AMERICA INTELLECTUAL PROPERTY CORPORATION, P.O. BOX 506, MERRIFIELD, VA, 22116, US

(21) Appl. No.: 11/867,693

(22) Filed: Oct. 5, 2007

(30) Foreign Application Priority Data
May 10, 2007 (TW) 096116672

(51) Int. Cl. H01L 33/00

(52) U.S. Cl. 257/99; 257/E33.056; 257/E33.062

(57) ABSTRACT

A surface light emitting diode module includes a conductive substrate including a first electrode section. A first hole is formed on the first electrode section. The surface light emitting diode module further includes a surface light emitting diode installed on the conductive substrate. The surface light emitting diode includes a first electrode pin for contacting with the first electrode section. A second hole is formed on the first electrode pin and disposed in a position corresponding to the first hole. The surface light emitting diode module further includes a first fixing component passing through the second hole and the first hole so as to fix the conductive substrate and the surface light emitting diode.

### BACKGROUND OF THE INVENTION

1. Field of the Invention

The present invention relates to a surface light emitting diode module, and more particularly, to a surface light emitting diode module with a surface light emitting diode connected to a conductive substrate tightly.

2. Description of the Prior Art

Recently, new application fields of high-illumination light emitting diodes (LEDs) have been developed. Different from a common incandescent light, a cold illumination light emitting diode has the advantages of low power consumption, long device lifetime, no idle time, and quick response speed. In addition, since light emitting diodes also have the advantages of small size, vibration resistance, suitability for mass production, and easy fabrication as a tiny device or an array device, they have been widely applied in display apparatuses and indicating lamps of information, communication, and consumer electronics products. Light emitting diodes are not only utilized in outdoor traffic signal lamps or various outdoor displays, but also are very important components in the automotive industry, such as a brake light, an indicator, and so on. Generally, surface light emitting diodes, such as SNAP light emitting diodes, are utilized as light sources of brake lights and indicators in the automotive industry.

The surface light emitting diodes are disposed on a conductive substrate in a soldering manner or a stamping manner practically. For example, U.S. Pat. No. 5,519,596, U.S. Pat. No. 5,404,282, U.S. Pat. No. 7,070,418, U.S. Pat. No. 6,335,548, U.S. Pat. No. 6,521,916, U.S. Pat. No. 6,849,867, U.S. Pat. No. 6,828,170, USD432095 disclose several kinds of shapes and structures of surface light emitting diodes. However, there is a problem of exposed soldering tin and poor joint intensity when the surface light emitting diode is disposed on the conductive substrate in a laser spot welding manner. In addition, the surface light emitting diode and the conductive substrate cannot be separated again after combination, so the broken surface light emitting diode cannot be replaced. The brake light and the indicator are in an operating condition with high-temperature, high current, and high vibration. The joint intensity of the surface light emitting diode and the conductive substrate might reduce due to the high operating temperature of the surface light emitting diode causing melt of the soldering tin. The surface light emitting diode also might separate from the conductive substrate due to vibration. Besides, the surface light emitting diode and the conductive substrate might deform in the stamping manner so as to reduce the uniformity and smoothness of the product. There is a need to find an effective joint mechanism of the surface light emitting diode and the conductive substrate.

### SUMMARY OF THE INVENTION

It is therefore a primary objective of the claimed invention to provide a surface light emitting diode module with a surface light emitting diode connected to a conductive substrate tightly for solving the above-mentioned problem.

According to the claimed invention, a surface light emitting diode module includes a conductive substrate including a first electrode section. A first hole is formed on the first electrode section. The surface light emitting diode module further includes a surface light emitting diode installed on the conductive substrate. The surface light emitting diode includes a first electrode pin for contacting with the first electrode section. A second hole is formed on the first electrode pin and disposed in a position corresponding to the first hole. The surface light emitting diode module further includes a first fixing component passing through the second hole and the first hole so as to fix the conductive substrate and the surface light emitting diode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing of a surface light emitting diode module according to a preferred embodiment of the present invention.

FIG. 2 is an exploded diagram of the surface light emitting diode module according to the preferred embodiment of the present invention.

FIG. 3 is a diagram of a first component and a second fixing component passing through a conductive substrate and a surface light emitting diode according to the preferred embodiment of the present invention.

FIG. 4 is a diagram of the first component and the second fixing component passing through the conductive substrate and the surface light emitting diode according to another embodiment of the present invention.

### DETAILED DESCRIPTION

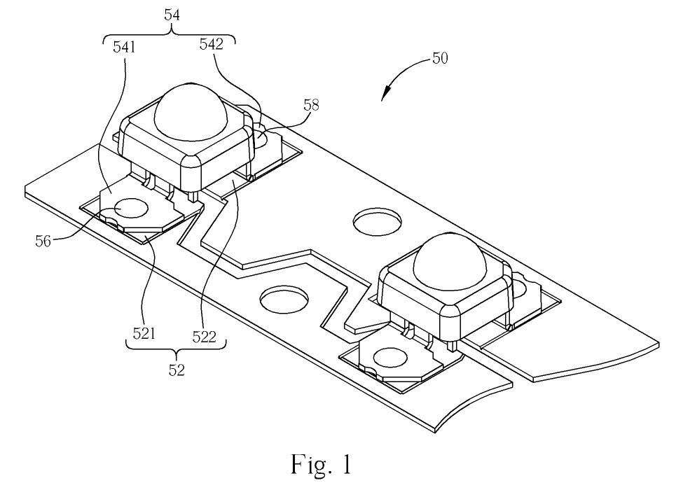

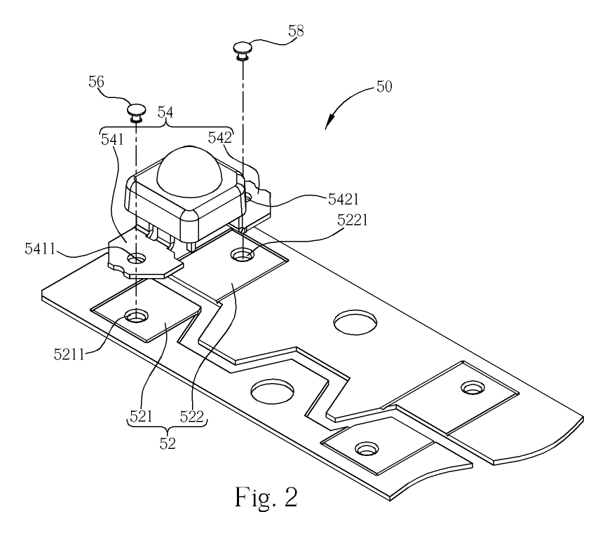

Please refer to FIG. 1 and FIG. 2. FIG. 1 is a schematic drawing of a surface light emitting diode module 50 according to a preferred embodiment of the present invention. FIG. 2 is an exploded diagram of the surface light emitting diode module 50 according to the preferred embodiment of the present invention. The surface light emitting diode module 50 includes a conductive substrate 52 including a first electrode section 521 and a second electrode section 522. The first electrode section 521 can be an anode section, and the second electrode section 522 can be a cathode section. The first electrode section 521 can be a cathode section, and the second electrode section 522 can be an anode section. The first electrode section 521 and the second electrode section 522 are insulated. The first electrode section 521 and the second electrode section 522 of the conductive substrate 52 are electrically connected to an external power source. The surface light emitting diode module 50 further includes at least one surface light emitting diode 54 installed on the conductive substrate 52. The surface light emitting diode 54 can be a SNAP light emitting diode. The surface light emitting diode 54 includes a first electrode pin 541 for contacting with the first electrode section 521, and a second electrode pin 542 for contacting with the second electrode section 522. The surface light emitting diode 54 receives electricity from the external power source via the connection of the first electrode pin 541 and the first electrode section 521 and the connection of the second electrode pin 542 and the second electrode section 522 so as to emit light. In addition, a first hole 5211 is formed on the first electrode section 521 of the conductive substrate 52. A second hole 5411 is formed on the first electrode pin 541 and disposed in a position corresponding to the first hole 5211. A third hole 5221 is formed on the second electrode section 522 of the conductive substrate 52. A fourth hole 5421 is formed on the second electrode pin 542 and disposed in a position corresponding to the third hole 5221.

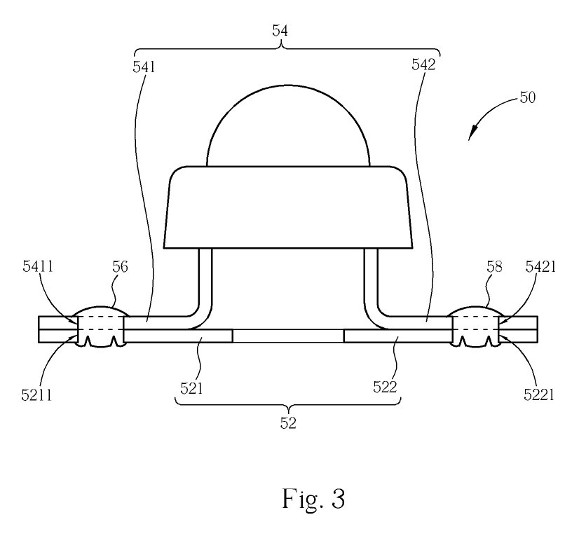

The surface light emitting diode module 50 further includes a first fixing component 56 passing through the second hole 5411 and the first hole 5211, and a second fixing component 58 passing through the third hole 5221 and the fourth hole 5421 so as to fix the conductive substrate 52 and the surface light emitting diode 54. Please refer to FIG. 3. FIG. 3 is a diagram of the first component 56 and the second fixing component 58 passing through the conductive substrate 52 and the surface light emitting diode 54 according to the preferred embodiment of the present invention. The first fixing component 56 and the second fixing component 58 can be rivets. The first fixing component 56 passes through the second hole 5411 of the first electrode pin 541 and the first hole 5211 of the first electrode section 521. The second fixing component 58 passes through the fourth hole 5421 of the second electrode pin 542 and the third hole 5221 of the second electrode section 522. The first fixing component 56 and the second fixing component 58 can fix the first electrode pin 541 and the second electrode pin 542 of the surface light emitting diode 54 on the first electrode section 521 and the second electrode section 522 of the conductive substrate 52 as a mechanical connection interface of the conductive substrate 52 and the surface light emitting diode 54. The first fixing component 56 and the second fixing component 58 can be made of conductive material, such as metal material so that the first fixing component 56 and the second fixing component 58 can be not only a mechanical connection interface but also an electrical connection interface of the conductive substrate 52 and the surface light emitting diode 54.

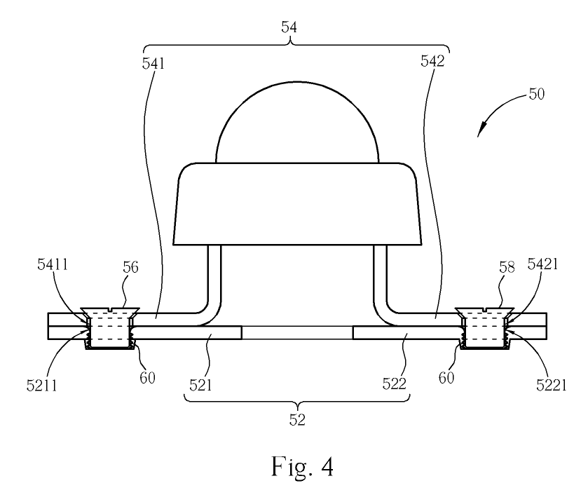

Please refer to FIG. 4. FIG. 4 is a diagram of the first component 56 and the second fixing component 58 passing through the conductive substrate 52 and the surface light emitting diode 54 according to another embodiment of the present invention. The first fixing component 56 and the second fixing component 58 can be screws, such as conductive screws. Threads 60 are formed inside the first hole 5211 and the third hole 5221 of the conductive substrate 52 respectively. The first fixing component 56 passes through the second hole 5411 of the first electrode pin 541 and is screwed in the thread 60 inside the first hole 5211 of the first electrode section 521. The second fixing component 58 passes through the fourth hole 5421 of the second electrode pin 542 and is screwed in the thread 60 inside the third hole 5221 of the second electrode section 522. The first fixing component 56 and the second fixing component 58 can fix the first electrode pin 541 and the second electrode pin 542 of the surface light emitting diode 54 on the first electrode section 521 and the second electrode section 522 of the conductive substrate 52 respectively as the mechanical connection interface. If the first fixing component 56 and the second fixing component 58 are conductive screws, the first fixing component 56 and the second fixing component 58 can be not only the mechanical connection interface but also an electrical connection interface of the conductive substrate 52 and the surface light emitting diode 54.

The fixing components of the present invention can be rivets, screws, or other mechanical components. The first fixing component 56 and the second fixing component 58 can be different mechanical components. For example, the first fixing component 56 is a rivet, and the second fixing component 58 is a screw. The holes of the conductive substrate 52 and the surface light emitting diode 54 need to correspond with the first fixing component 56 and the second fixing component 58.

In contrast to the prior art, the surface light emitting diode module of the present invention utilizes the fixing components passing through the electrode sections of the conductive substrate and the electrode pins of the surface light emitting diode as the mechanical connection interface. If the fixing components are made of conductive material, the fixing components can be not only the mechanical connection interface but also an electrical connection interface of the conductive substrate and the surface light emitting diode. The joint mechanism of the present invention can increase joint intensity of the conductive substrate and the surface light emitting diode. The fixing components are installed inside the holes of the conductive substrate and the surface light emitting diode in a detachable manner as a recoverable joint mechanism. That is, when a broken surface light emitting diode is installed on the conductive substrate, the broken surface light emitting diode can be replaced by detaching the fixing components. Furthermore, the joint mechanism of the surface light emitting diode module of the present invention can be applied in the brake light and the indicator at an operating condition with high-temperature, high current, and high vibration. The surface light emitting diode and the conductive substrate do not deform so as to keep the uniformity and smoothness of the product. In conclusion, the present invention provides an effective joint mechanism of the surface light emitting diode and the conductive substrate.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A surface light emitting diode module comprising:
a conductive substrate comprising a first electrode section, a first hole being formed on the first electrode section;
a surface light emitting diode installed on the conductive substrate, the surface light emitting diode comprising a first electrode pin for contacting with the first electrode section, a second hole being formed on the first electrode pin and disposed in a position corresponding to the first hole; and
a first fixing component passing through the second hole and the first hole so as to fix the conductive substrate and the surface light emitting diode.

2. The surface light emitting diode module of claim 1 wherein the first electrode section is an anode section or a cathode section.

3. The surface light emitting diode module of claim 1 wherein the surface light emitting diode is a SNAP light emitting diode.

4. The surface light emitting diode module of claim 1 wherein the first fixing component is a rivet.

5. The surface light emitting diode module of claim 1 wherein the first fixing component is a screw.

6. The surface light emitting diode module of claim 5 wherein the screw is a conductive screw.

7. The surface light emitting diode module of claim 5 wherein a thread is formed inside the first hole of the conductive substrate and the screw is screwed in the thread.

8. The surface light emitting diode module of claim 1 wherein the conductive substrate further comprises a second electrode section, a third hole is formed on the second electrode section, the surface light emitting diode further comprises a second electrode pin for contacting with the second electrode section, a fourth hole is formed on the second electrode pin and disposed in a position corresponding to the third hole, and the surface light emitting diode module further comprises a second fixing component passing through the third hole and the fourth hole so as to fix the conductive substrate and the surface light emitting diode.

9. The surface light emitting diode module of claim 8 wherein the second electrode section is an anode section or a cathode section.

10. The surface light emitting diode module of claim 8 wherein the second fixing component is a rivet.

11. The surface light emitting diode module of claim 8 wherein the second fixing component is a screw.

12. The surface light emitting diode module of claim 11 wherein the screw is a conductive screw.

13. The surface light emitting diode module of claim 11 wherein a thread is formed inside the third hole of the conductive substrate and the screw is screwed in the thread.

14. The surface light emitting diode module of claim 8 wherein the first electrode section and the second electrode section are insulated.
